(19) United States
(12) Patent Application Publication
(10) Pub. No.: US 2024/0203832 A1
(43) Pub. Date: Jun. 20, 2024

(54) Semiconductor device and semiconductor device manufacturing method

(71) Applicant: Tokyo Electron Limited, Tokyo (JP)

(72) Inventors: Tetsu OHTOU, Tokyo (JP); Tomonari YAMAMOTO, Tokyo (JP); Koji WATANABE, Tokyo (JP)

(21) Appl. No.: 18/518,256

(22) Filed: Nov. 22, 2023

(30) Foreign Application Priority Data
Nov. 25, 2022 (JP) 2022-188104

(51) Int. Cl. H01L 23/48

(52) U.S. Cl. CPC H01L 23/481

(57) ABSTRACT

[Object] A technique for increasing decoupling capacitance between a power supply line and a ground line in a semiconductor device is provided.

[Solution] A semiconductor device according to the present disclosure includes a substrate having a first main surface and a second main surface, a plurality of elements formed on the first main surface of the substrate or above the first main surface, at least one first power supply line electrically connected to at least one of the plurality of elements, disposed in a first layer provided above the first main surface of the substrate, and having an upper surface, a first side surface continuously formed from the upper surface, and a second side surface that is opposite to the first side surface and continuously formed from the upper surface, and at least one second power supply line disposed in the first layer and a second layer above the first layer and disposed from the second layer to the first layer to cover the upper surface, the first side surface, and the second side surface in a part of the at least one first power supply line.

### TECHNICAL FIELD

Exemplary embodiments of the present disclosure relate to a semiconductor device and a semiconductor device manufacturing method.

### BACKGROUND ART

There is a semiconductor device described in Patent Document 1 as a semiconductor device having an interconnect level structure.

### CITATION LIST

### Patent Documents

Patent Document 1: JP2022-16404A

### SUMMARY OF INVENTION

### Technical Problem

The present disclosure provides a technique for increasing decoupling capacitance between a power supply line and a ground line in a semiconductor device.

### Solution to Problem

A semiconductor device according to one exemplary embodiment of the present disclosure is provided. The semiconductor device includes a substrate having a first main surface and a second main surface, a plurality of elements formed on the first main surface of the substrate or above the first main surface, at least one first power supply line electrically connected to at least one of the plurality of elements, disposed in a first layer provided above the first main surface of the substrate, and having an upper surface, a first side surface continuously formed from the upper surface, and a second side surface that is opposite to the first side surface and continuously formed from the upper surface, and at least one second power supply line disposed in the first layer and a second layer above the first layer and disposed from the second layer to the first layer to cover the upper surface, the first side surface, and the second side surface in a part of the at least one first power supply line.

### Advantageous Effects of Invention

According to one exemplary embodiment of the present disclosure, a technique of increasing decoupling capacitance between a power supply line and a ground line in a semiconductor device can be provided.

### BRIEF DESCRIPTION OF DRAWINGS

FIG. 1 is a cross-sectional view schematically illustrating an example of a structure of a semiconductor device 100.

FIG. 2A is a view illustrating an example of a process of manufacturing the semiconductor device 100.

FIG. 2B is a view illustrating an example of a process of manufacturing the semiconductor device 100.

FIG. 2C is a view illustrating an example of a process of manufacturing the semiconductor device 100.

FIG. 2D is a view illustrating an example of a process of manufacturing the semiconductor device 100.

FIG. 2E is a view illustrating an example of a process of manufacturing the semiconductor device 100.

FIG. 2F is a view illustrating an example of a process of manufacturing the semiconductor device 100.

FIG. 2G is a view illustrating an example of a process of manufacturing the semiconductor device 100.

FIG. 2H is a view illustrating an example of a process of manufacturing the semiconductor device 100.

FIG. 3 is a cross-sectional view schematically illustrating another example of the structure of the semiconductor device 100.

FIG. 4 is a cross-sectional view schematically illustrating still another example of the structure of the semiconductor device 100.

### DESCRIPTION OF EMBODIMENTS

Hereinafter, embodiments of the present disclosure will be described.

In one exemplary embodiment, a semiconductor device is provided. The semiconductor device includes a substrate having a first main surface and a second main surface, a plurality of elements formed on the first main surface of the substrate or above the first main surface, at least one first power supply line electrically connected to at least one of the plurality of elements, disposed in a first layer provided above the first main surface of the substrate, and having an upper surface, a first side surface continuously formed from the upper surface, and a second side surface that is opposite to the first side surface and continuously formed from the upper surface, and at least one second power supply line disposed in the first layer and a second layer above the first layer and disposed from the second layer to the first layer to cover the upper surface, the first side surface, and the second side surface in a part of the at least one first power supply line.

One exemplary embodiment further includes at least two signal lines electrically connected to at least one of the plurality of elements and disposed in at least the first layer.

In one exemplary embodiment, the at least two signal lines are disposed from the second layer to the first layer.

One exemplary embodiment further includes a first dielectric film disposed between the at least two signal lines in the first layer and having a first dielectric constant, and a second dielectric film disposed between the at least one first power supply line and the at least one second power supply line in the first layer and having a second dielectric constant higher than the first dielectric constant.

In one exemplary embodiment, in the first layer, a distance between the at least two signal lines is greater than a distance between the at least one first power supply line and the at least one second power supply line.

In one exemplary embodiment, in the first layer, each of the at least two signal lines includes a wiring portion and a plug portion, in the first layer, the at least one first power supply line includes a wiring portion and a plug portion, and a length of the plug portion of each of the at least two signal lines is greater than a length of the plug portion of the at least one first power supply line.

In one exemplary embodiment, the at least one first power supply line and the at least one second power supply line are disposed to intersect each other in a plan view of the first main surface.

In one exemplary embodiment, a cross-sectional area of the at least one first power supply line is greater than a cross-sectional area of each of the at least two signal lines.

In one exemplary embodiment, the second power supply line is a ground line.

One exemplary embodiment includes a substrate having a first main surface and a second main surface, a plurality of elements formed on the first main surface of the substrate or above the first main surface, at least one first power supply line electrically connected to at least one of the plurality of elements, disposed in a first layer provided below the second main surface of the substrate, and having a lower surface, a first side surface continuously formed from the lower surface, and a second side surface that is opposite to the first side surface and continuously formed from the lower surface, and at least one second power supply line disposed in the first layer and a second layer below the first layer and disposed from the second layer to the first layer to cover the lower surface, the first side surface, and the second side surface in a part of the at least one first power supply line.

One exemplary embodiment further includes at least two signal lines electrically connected to at least one of the plurality of elements and disposed in a third layer that is provided above the first main surface.

One exemplary embodiment includes providing a substrate having a first main surface and a second main surface, forming a plurality of elements on the first main surface of the substrate or above the first main surface, forming at least one first power supply line electrically connected to at least one of the plurality of elements, disposed in a first layer provided above the first main surface of the substrate, and having a lower surface, a first side surface continuously formed from the lower surface, and a second side surface that is opposite to the first side surface and continuously formed from the lower surface, and forming at least one second power supply line disposed in a second layer above the first layer and disposed from the second layer to the first layer to cover the lower surface, the first side surface, and the second side surface in a part of the at least two power supply lines.

Hereinafter, each embodiment of the present disclosure will be described in detail with reference to the drawings. In the drawings, the same or similar elements are denoted by the same reference numerals, and overlapping descriptions thereof will be omitted. Unless otherwise specified, a positional relationship of up/down, left/right, or the like will be described based on a positional relationship illustrated in the drawings. The dimensional ratios in the drawings do not indicate actual ratios, and the actual ratios are not limited to the illustrated ratios.

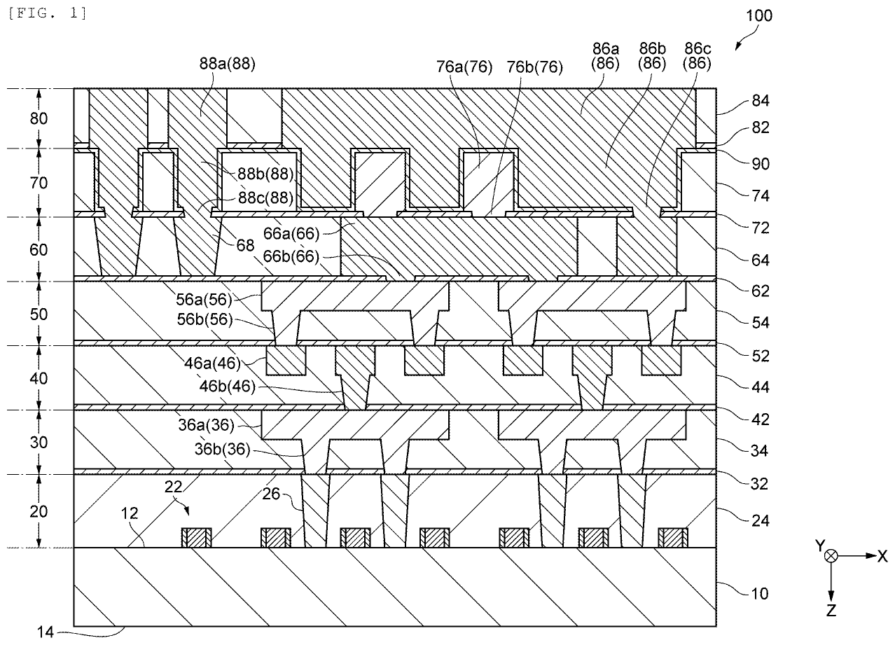

FIG. 1 is a cross-sectional view schematically illustrating an example of a structure of a semiconductor device 100 of the present disclosure. The semiconductor device 100 is configured to include a substrate 10, an element layer 20, and wiring layers 30 to 80. The semiconductor device 100 may be, for example, a logic device, a memory device, or an analog device.

The substrate 10 may be a semiconductor substrate. For example, the substrate 10 may be a semiconductor wafer configured to include a semiconductor material such as silicon (Si), germanium, or gallium arsenide. The substrate 10 includes a first main surface 12 that is a side where an element 22 is formed, and a second main surface 14 that is a surface opposite to the first main surface 12. At least a part of a structure of the element 22 may be formed in the substrate 10.

The element layer 20 is a layer in which a plurality of elements 22 are disposed. In the present embodiment, the element layer 20 is configured to include at least a part of structures of the plurality of elements 22, a dielectric film 24, and a plurality of plugs 26. A part of the structure of the plurality of elements 22 may be disposed on or formed in the substrate 10. The element 22 may be an active element such as a MOS transistor or a passive element such as a resistor or a capacitor. The dielectric film 24 may function as an interlayer insulating film. The dielectric film 24 may be configured to include a dielectric material or an insulating material. The plurality of plugs 26 are disposed in the element layer 20. The plurality of plugs 26 electrically connect the plurality of elements 22 to a plurality of wires 36. One ends of the plurality of plugs 26 may be connected to the plurality of elements 22 in the substrate 10. Further, one end of the plurality of plugs 26 may be connected to the plurality of elements 22 in the semiconductor layer 20. The plurality of plugs 26 may be configured to include a conductive material. The conductive material may be a metal material or a semiconductor material.

The wiring layer 30 may be configured to include dielectric films 32 and 34 and the plurality of wires 36. The dielectric films 32 and 34 may function as interlayer insulating films. The dielectric films 32 and 34 may be configured to include a dielectric material or an insulating material. Further, the dielectric film 32 may function as a so-called stopper during etching of the dielectric film 34. That is, the dielectric film 32 may be configured to include a material with an etching rate lower than an etching rate of the dielectric film 34 in the etching of the dielectric film 34. The etching can be etching in which grooves for forming the plurality of wires 36 are formed in the dielectric film 34. The plurality of wires 36 may each be configured to include a wiring portion 36a and a plug portion 36b. The plurality of wires 36 electrically connect the plurality of plugs 26 to a plurality of wires 46. The plug portions 36b of the plurality of wires 36 are connected to the plurality of plugs 26.

The wiring layer 40 may be configured to include dielectric films 42 and 44 and the plurality of wires 46. The dielectric films 42 and 44 may function as interlayer insulating films. The dielectric films 42 and 44 may be configured to include a dielectric material or an insulating material. Further, the dielectric film 42 may function as a so-called stopper in the etching of the dielectric film 44. That is, the dielectric film 42 may be configured to include a material with an etching rate lower than an etching rate of the dielectric film 44 in the etching of the dielectric film 44. The etching may be etching in which grooves for forming the plurality of wires 46 are formed in the dielectric film 44. The plurality of wires 46 may each be configured to include a wiring portion 46a and a plug portion 46b. The plurality of wires 46 electrically connect the plurality of wires 36 to a plurality of wires 56. The plug portion 46b of each of the plurality of wires 46 is connected to the wiring portion 36a of each of the plurality of wires 36.

A wiring layer 50 may be configured to include dielectric films 52 and 54 and the plurality of wires 56. The dielectric films 52 and 54 may function as interlayer insulating films. The dielectric films 52 and 54 may be configured to include a dielectric material or an insulating material. Further, the dielectric film 52 may function as a so-called stopper in etching of the dielectric film 54. That is, the dielectric film 52 may be configured to include a material with an etching rate lower than an etching rate of the dielectric film 54 in etching of the dielectric film 44. The etching may be etching in which grooves for forming the plurality of wires 56 are formed in the dielectric film 54. The plurality of wires 56 may each be configured to include a wiring portion 56a and a plug portion 56b. The plurality of wires 56 electrically connect the plurality of wires 56 and a plurality of wires 66. The plug portion 46b of each of the plurality of wires 56 is connected to the wiring portion 46a of each of the plurality of wires 46.

Wires disposed in the wiring layers 30 to 50 may be electrically connected to at least one of the element 22, a power supply line 76, a power supply line 86, and a signal line 88. For example, the wires disposed in the wiring layers 30 to 50 may electrically connect the element 22 to the power supply line 76 or 86. Further, the wires disposed in the wiring layers 30 to 50 may electrically connect the element 22 to the signal line 88. Further, the wires disposed in the wiring layers 30 to 50 may electrically connect the power supply lines 76 to each other, the power supply lines 86 to each other, or the signal lines 88 to each other. The power supply line 76 is an example of a first power supply line. Further, the ground line 86 is an example of a second power supply line.

The wiring layer 60 may be configured to include dielectric films 62 and 64 and wires 66 and 68. The dielectric films 62 and 64 may function as interlayer insulating films. The dielectric films 62 and 64 may be configured to include a dielectric material or an insulating material. Further, the dielectric film 62 may function as a so-called stopper in etching of the dielectric film 64. That is, the dielectric film 62 may be configured to include a material with an etching rate lower than an etching rate of the dielectric film 64 in etching of the dielectric film 44. The etching may be etching in which grooves for forming the plurality of wires 66 and/or 68 are formed in the dielectric film 64.

The plurality of wires 66 may each be configured to include a wiring portion 66a and a plug portion 66b. The plurality of wires 66 electrically connect the plurality of wires 66 and at least one of a plurality of power supply lines 76. The plug portion 46b of each of the plurality of wires 66 is connected to the wiring portions 56a of each of the plurality of wires 56. The wiring portion 66a of the wire 66 may be formed from the dielectric film 62 to a dielectric film 72 in a thickness direction of the wiring layer 60. That is, a thickness of the wiring portion 66a may be substantially equal to a thickness of the dielectric film 64. Further, a thickness of the plug portion 66b may be substantially equal to a thickness of the dielectric film 62.

The plurality of wires 68 may function as signal lines. That is, the plurality of wires 68 are electrically connected to the plurality of signal lines 88. Further, the plurality of wires 68 may be electrically connected to the plurality of elements 22 through other wiring layers disposed in the wiring layers 30 to 50. Like the wires 36, 46, and 56, the plurality of wires 68 may each include a wiring portion and a plug portion. In this case, the wiring portion of each of the plurality of wires 68 may be connected to each of the plurality of signal lines 88. Further, as illustrated in FIG. 1, a thickness of the wiring portion of each of the plurality of wires 68 may be substantially equal to a thickness of the dielectric film 64. The plug portion of each of the plurality of wires 68 may be connected to another wire disposed in the wiring layer 50. Further, a thickness of the plug portion of each of the plurality of wires 68 may be substantially equal to a thickness of the dielectric film 62.

The wiring layer 70 may be configured to include dielectric films 72 and 74, the plurality of power supply lines 76, the plurality of signal lines 88 (wiring portions 88b and plug portions 88c), and a high-dielectric film 90. The dielectric films 72 and 74 may function as interlayer insulating films. The dielectric films 72 and 74 may be configured to include a dielectric material or an insulating material. Further, the dielectric film 72 may function as a so-called stopper in etching of the dielectric film 74. That is, the dielectric film 72 may be configured to include a material with an etching rate lower than an etching rate of the dielectric film 74 in etching of the dielectric film 74. The etching may be etching in which grooves for forming the plurality of power supply lines 76, the plurality of signal lines 88 (wiring portions 88b), and a part of the ground line 86 are formed in the dielectric film 74. Further, the wiring layer 80 may be configured to include dielectric films 82 and 84, a plurality of ground lines 86, and the plurality of signal lines 88 (wiring portions 88a). The dielectric films 82 and 84 may function as interlayer insulating films. The dielectric films 82 and 84 may be configured to include a dielectric material or an insulating material.

The power supply line 76 is configured to include a wiring portion 76a and a plug portion 76b. A thickness of the wiring portion 76a may be substantially equal to a thickness of the dielectric film 74 in a thickness direction of the wiring layer 70. Further, the wiring portion 76a has an upper surface and a side surface. Further, a thickness of the wiring portion 76a may be greater than a thickness of the wiring portion 88b of the signal line 88.

The ground line 86 is configured to include a wiring portion 86b, a wiring portion 86b, and a plug portion 86c. A thickness of the wiring portion 86a may be substantially equal to a thickness of the wiring layer 80 or the dielectric film 84 in a thickness direction of the wiring layer 80. Further, a thickness of the wiring portion 86b may be substantially equal to thicknesses of the dielectric film 74 and the high-dielectric film 90 in a thickness direction of the wiring layer 70. Further, the thickness of the wiring portion 86b may be substantially equal to the thickness of the wiring layer 70 or the dielectric film 74. Further, a cross-sectional area of the power supply line 76 and/or the ground line 86 may be greater than a cross-sectional area of the signal line 88.

For example, the power supply line 76 and the signal line 88 may be wires disposed mainly in a Y-axis direction illustrated in FIG. 1. Further, the ground line 86 may be a wire disposed mainly in an X-axis direction illustrated in FIG. 1. That is, the power supply line 76 and the ground line 86 may be disposed to intersect each other in a plan view of the first main surface 12 of the substrate 10. The power supply line 76 and the ground line 86 may be substantially orthogonal to each other in a plan view of the first main surface 12 of the substrate 10. Further, the ground line 86 includes a portion formed from the wiring layer 80 to the wiring layer 70, in a portion intersecting with the power supply line 76. Specifically, the ground line 86 is configured to include the wiring portion 86a in the wiring layer 80, the wiring portion 86b in the wiring layer 70, and the plug portion 86c. The wiring portion 86b is a portion protruding from the wiring portion 86a in a direction from the wiring layer 80 toward the wiring layer 70. The direction from the wiring layer 80 toward the wiring layer 70 is the Z-axis direction illustrated in FIG. 1.

For example, in one cross-section of the semiconductor device 100, the plurality of power supply lines 76 and the plurality of wiring portions 86b may be alternately disposed in the X-axis direction in the wiring layer 70. Further, the plurality of power supply lines 76 and the plurality of wiring portions 86b may be disposed adjacent to each other. That is, at least one of the wiring portions 86b of the ground lines 86 may be disposed between the plurality of wiring portions 76a in the wiring layer 70. At least one of the wiring portions 76a of the power supply lines 76 may be disposed between the plurality of wiring portions 86b in the wiring layer 70.

The signal line 88 is configured to include the wiring portion 88a, the wiring portion 88b, and the plug portion 88c. A thickness of the wiring portion 88b may be less than a thickness of the wiring portion 76a of the power supply line 76. Further, a length of the plug portion 88c may be greater than a length of the plug portion 76b of the power supply line 76. The plurality of signal lines 88 (wiring portions 88b) adjacent to each other may be separated from each other with the dielectric film 74 interposed therebetween. Further, the ground line 86 and the adjacent signal line 88 (wiring portion 88a) may be separated from each other with the dielectric film 74 and the high-dielectric film 90 interposed therebetween.

The high-dielectric film 90 is configured to include a dielectric material with a high dielectric constant. A dielectric constant of a dielectric material included in the high-dielectric film 90 is higher than a dielectric constant of a dielectric material included in the dielectric film 74. For example, the dielectric material included in the high-dielectric film 90 may be a metal oxide or a metal nitride. The dielectric material may be a mixture of a plurality of metal oxides, a mixture of a plurality of metal nitrides, or a mixture of one or more metal oxides and one or more metal nitrides. For examples, the metal oxide may include hafnia (HfO₂), zirconia (ZrO₂), or alumina (Al₂O₃). For example, the metal nitride may include hafnium nitride (HfN), zirconium nitride (ZrN), or aluminum nitride (AlN). Further, for example, the high-dielectric film 90 may be disposed between the wiring portion 76a and the wiring portion 86a, between the wiring portion 76a and the wiring portion 86b (a side surface of the wiring portion 76a and a side surface of the wiring portion 86b), between the dielectric film 74 and the wiring portion 86b (a side surface of the wiring portion 86b), between the dielectric film 74 and the wiring portion 86a (a side surface of the wiring portion 86b), and between the dielectric film 64 and/or the dielectric film 72 and the wiring portion 86b (a lower surface of the wiring portion 86b). That is, the high-dielectric film 90 may be disposed to cover an upper surface and a side surface of the wiring portion 76a, a lower surface of the wiring portion 86a, and a lower surface and a side surface of the wiring portion 86b. Further, the high-dielectric film 90 may be disposed between the dielectric film 74 and the dielectric film 82 and/or the dielectric film 84, and between the wiring portion 88b of the signal line 88 and the dielectric film 82 and/or the dielectric film 84.

The semiconductor device 100 may further include a layer identical to one or more of the wiring layers 30 to 80 above the wiring layer 80. Further, the semiconductor device 100 may further include any number of wiring layers/element layers below the wiring layer 80. Further, the wiring layers 30 to 50 may include wires electrically connected to the signal line 88. The semiconductor device 100 may include elements, wires, and/or dielectric films, which are not illustrated in FIG. 1, in another cross-section of the semiconductor device 100.

Wires, signal lines, power supply lines, and ground lines (hereinafter, also referred to as “wires and the like”) included in the wiring layers 30 to 80 are configured to include a metal material. For example, the metal material may be copper (Cu). Further, the wire or the like may be a stacked wire in which a plurality of materials are stacked. For example, the stacked wire may include a barrier film. For example, the barrier film may include tantalum nitride (TaN) and/or cobalt (Co).

Further, for example, dielectric films included in the wiring layers 30 to 80 may each include a silicon oxide. For example, the dielectric films may each include a spin-on-glass (SOG). Further, the dielectric films included in the wiring layers 30 to 80 may each be a stacked film in which films configured to include the dielectric materials are stacked.

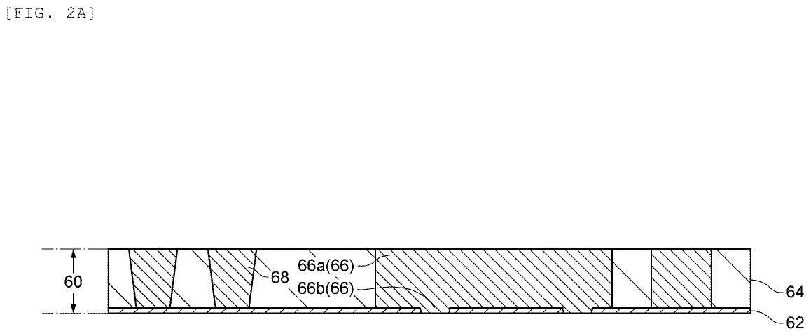

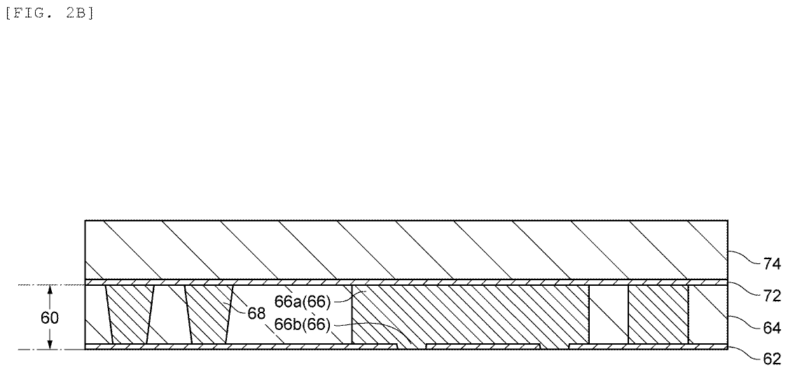

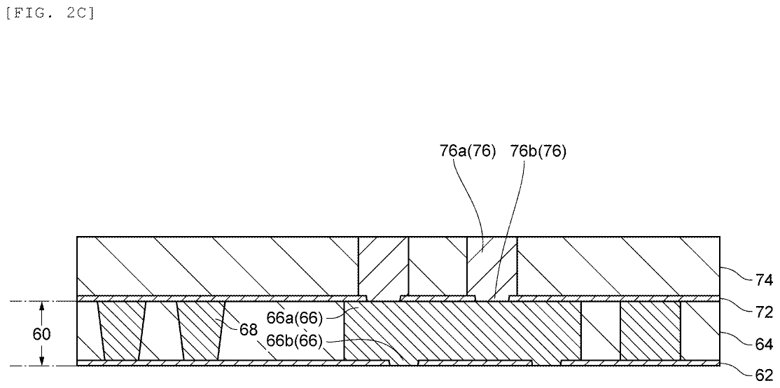

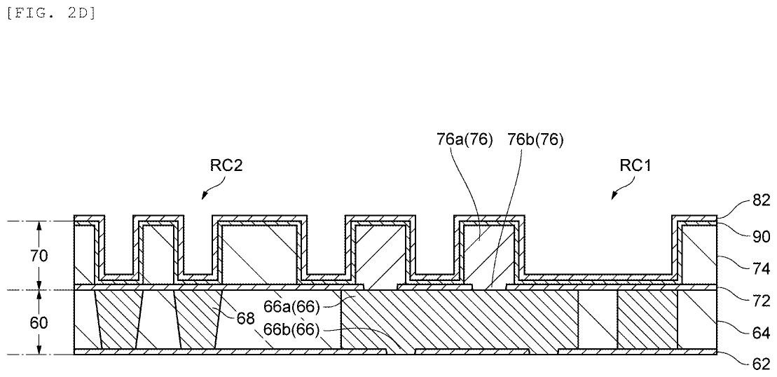

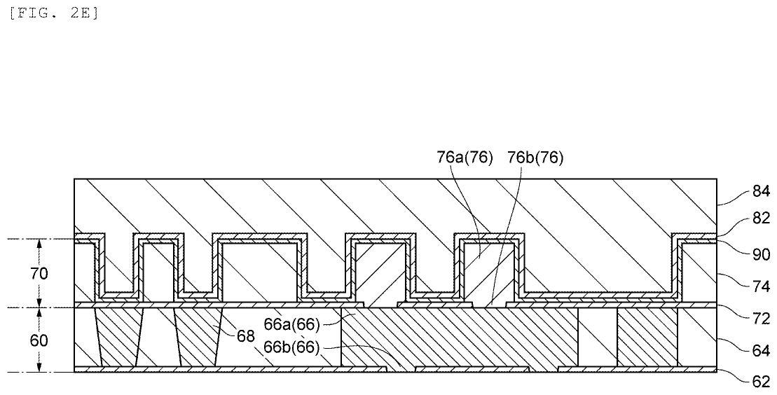

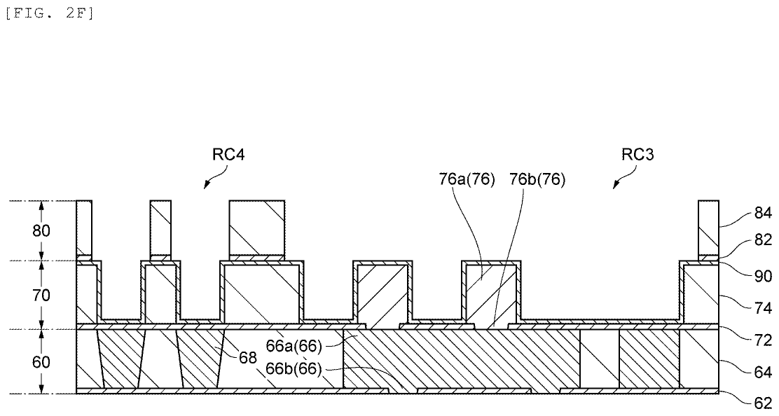

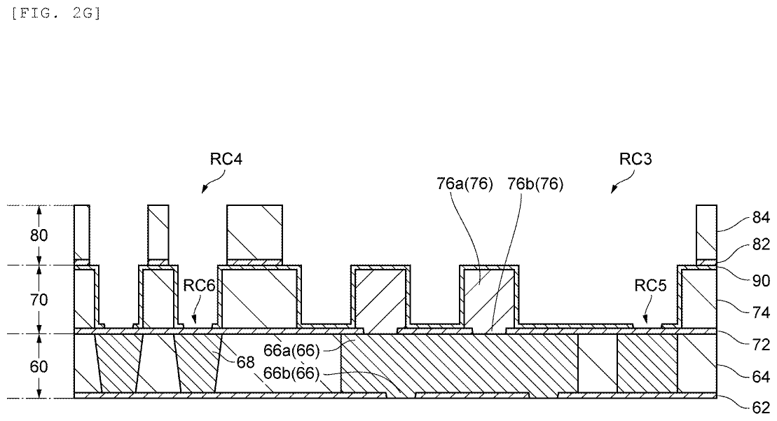

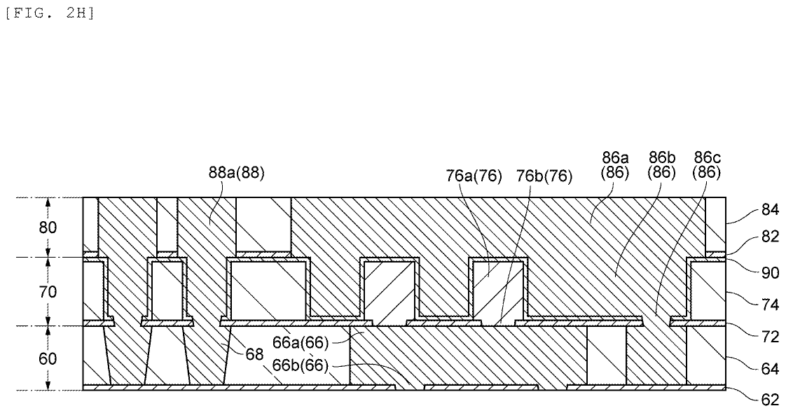

FIGS. 2A to 21 are views illustrating examples of a process of manufacturing the semiconductor device 100. In FIGS. 2A to 21, wiring layers 60 to 80 in the semiconductor device 100 are illustrated for the sake of convenience of description.

As illustrated in FIGS. 2A and 2B, after the wiring layer 60 is formed, the dielectric film 72 and the dielectric film 74 are formed on the wiring layer 60. Next, a recess portion where the power supply line 76 is formed is formed in the dielectric film 72 and the dielectric film 74. For example, the recess portion includes a recess portion where the plug portion 76b is formed and a recess portion where the wiring portion 76a is formed. For example, after the recess portion where the plug portion 76b is formed is formed in the dielectric film 72 (and the dielectric film 74), the recess portion where the wiring portion 76a is formed may be formed in the dielectric film 74. Next, a metal film is formed on the dielectric film 72 and the dielectric film 74 to fill the recess portion. Next, when a part of the metal film is removed by CMP or etching, the power supply line 76 is formed in the wiring layer 70 as illustrated in FIG. 2C.

Next, as illustrated in FIG. 2D, recess portions RC1 and RC2, the high-dielectric film 90, and the dielectric film 82 are formed in the wiring layer 70 (the dielectric film 74). The recess portion RC1 may include a recess portion where the ground line 86 is formed. The recess portion RC2 may include a recess portion where the signal line 88 is formed. For example, the recess portions RC1 and RC2 may be formed in the dielectric film 74 through patterning by photolithography and etching by plasma. The recess portions RC1 and RC2 are formed such that a part of the dielectric film 72 is exposed at bottom portions thereof.

Then, as illustrated in FIG. 2D, the high-dielectric film 90 and the dielectric film 82 are formed. The high-dielectric film 90 is formed on the dielectric film 72 and the dielectric film 74. The high-dielectric film 90 may be formed on an upper surface of the dielectric film 74, a side surface of the dielectric film 74, and a part of an upper surface of the dielectric film 72. The recess portions RC1 and RC2 may be defined by a side surface of the dielectric film 72 and the upper surface of the dielectric film 72. Further, as illustrated in FIG. 2D, the dielectric film 82 is formed on the high-dielectric film 90.

Next, as illustrated in FIG. 2E, the dielectric film 84 is formed. The dielectric film 84 may be formed on the dielectric film 82 to fill the recess portions RC1 and RC2 illustrated in FIG. 2D. A surface of the dielectric film 84 may be planarized by CMP or etching.

Next, as illustrated in FIG. 2F, recess portions RC3 and RC4 are formed in the wiring layers 70 and 80. The recess portion RC3 may include a recess portion where the ground line 86 is formed. The recess portion RC4 may include a recess portion where the signal line 88 is formed. For example, the recess portions RC3 and RC4 may be formed in the wiring layers 70 and 80 through patterning by photolithography and etching by plasma. For example, the recess portions RC3 and RC4 may be formed by selectively etching the dielectric films 74, 82, and 84 with respect to the high-dielectric film 90.

Next, as illustrated in FIG. 2G, recess portions RC5 and RC6 are formed. The recess portions RC5 and RC6 may be formed by removing a part of the high-dielectric film 90 and a part of the dielectric film 72 at bottom portions of the recess portions RC3 and RC4. For example, the recess portions RC5 and RC6 may be formed through patterning by photolithography and etching by plasma. The recess portion RC5 may be formed by selectively etching a part of the high-dielectric film 90 and a part of the dielectric film 72 with respect to the wire 66. Further, the recess portion RC6 may be formed by selectively etching a part of the high-dielectric film 90 and a part of the dielectric film 72 with respect to the wire 68. The recess portion RC5 includes a recess portion where the plug portion 86c of the ground line 86 is formed. Further, the recess portion RC6 includes a recess portion where the plug portion 88c of the signal line 88 is formed.

The recess portions RC3 and RC4 may be formed after the recess portions RC5 and RC6 are formed. That is, first, after the dielectric film 84 is formed in FIG. 2E, the dielectric films 84 and 82, the high-dielectric film 90, and the dielectric film 72 are etched, and thereby, the recess portions RC5 and RC6 may be formed. Then, the dielectric films 84 and 82 may be etched to form the recess portions RC3 and RC4.

Next, as illustrated in FIG. 2H, the ground line 86 and the signal line 88 are formed. That is, first, a metal film is formed to fill the recess portions RC3 to RC6. Then, the ground line 86 and the signal line 88 may be formed by removing the metal film until an upper surface of the dielectric film 84 is exposed through CMP or etching.

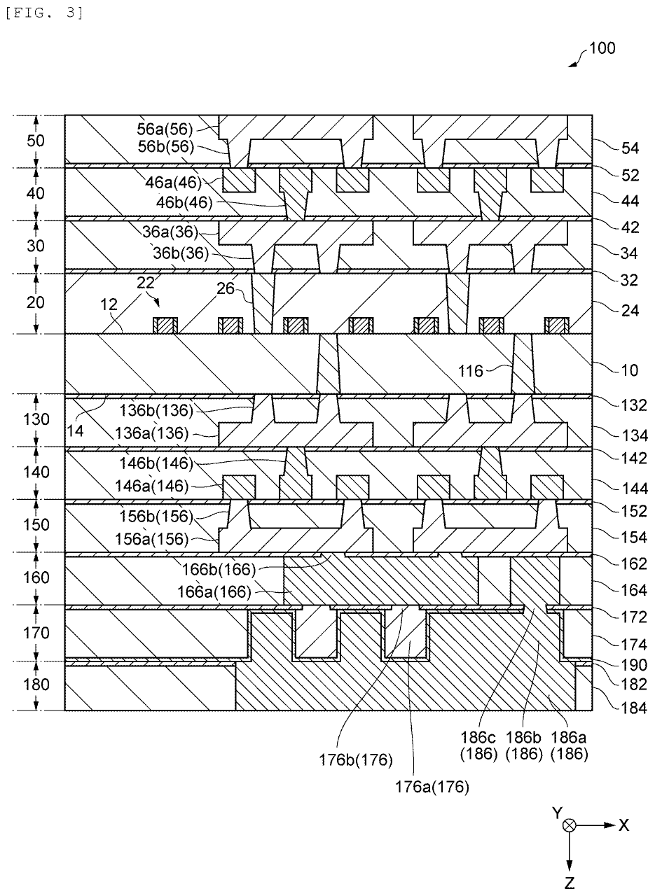

FIG. 3 is a cross-sectional view schematically illustrating another example of the structure of the semiconductor device 100. In the example illustrated in FIG. 3, the wiring layers 30 to 50 are disposed above the main surface 12 of the substrate 10. Further, wiring layers 130 to 180 are disposed below the second main surface 14 of the substrate 10. The wiring layers 130 to 180 may have the same configurations and/or functions as the wiring layers 30 to 80 illustrated in FIG. 1. Wires 136 to 166 may have the same configurations and/or functions as the wires 36 to 66 illustrated in FIG. 1. Further, a power supply line 176 and a ground line 186 may respectively have the same configuration and/or function as the power supply line 76 and the ground line 86 illustrated in FIG. 1.

In the example illustrated in FIG. 3, the wires 36 to 56 may be signal lines or wires electrically connected to the signal lines. Further, the wires 136 to 166 may be wires electrically connected to the power supply line 176 or the ground line 186. A plurality of plugs 116 are electrically connected to the plurality of elements 22 and a plurality of wires 136. One ends of the plurality of plugs 116 may be connected to the wire 136 on the main surface 14 of the substrate 10. Further, the plurality of plugs 116 may have the other ends connected to the plurality of elements 22 in the substrate 10. That is, the plurality of plugs 116 may be formed from the main surface 14 to the plurality of elements 22 inside the substrate 10.

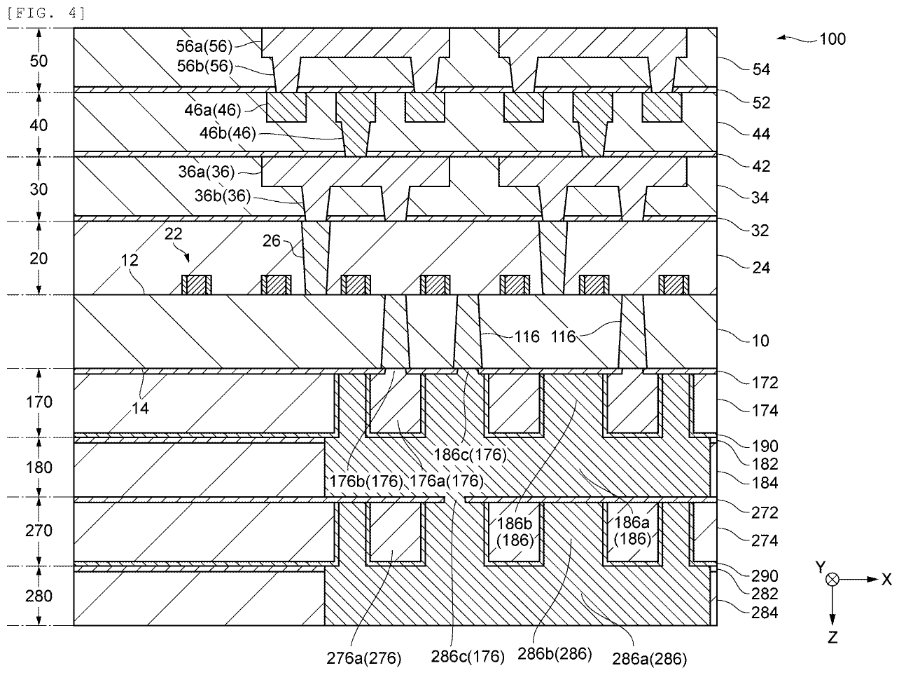

FIG. 4 is a cross-sectional view schematically illustrating still another example of the structure of the semiconductor device 100. In the example illustrated in FIG. 4, the wiring layers 30 to 50 are disposed above the main surface 12 of the substrate 10. Further, wiring layers 170 and 180 are disposed below the second main surface 14 of the substrate 10. That is, the semiconductor device 100 illustrated in FIG. 4 is different from the semiconductor device 100 illustrated in FIG. 3 in that there are no wiring layers 130 to 150 illustrated in FIG. 3. In the example illustrated in FIG. 4, one ends of the plurality of plugs 116 may be connected to the power supply line 176 and the ground line 186 on the main surface 14 of the substrate 10. Further, the plurality of plugs 116 may have the other ends connected to the plurality of elements 22 in the substrate 10.

In the example illustrated in FIG. 4, wiring layers 270 and 280 may be further disposed below the wiring layers 170 and 180. The wiring layers 270 and 280 may respectively have the same configuration and/or function as the wiring layers 170 and 180. Further, a power supply line 276 may be connected to the power supply line 176. A ground line 286 may be connected to the ground line 186. A dielectric film 272 may be formed of a material with a dielectric constant higher than a dielectric constant of a dielectric film 274. For example, the dielectric film 272 may be formed of the same material as a high-dielectric film 290.

According to an embodiment of the present disclosure, in the semiconductor device, decoupling capacitance between a power supply line and a ground line can be increased while suppressing parasitic capacitance between signal lines. Further, according to an embodiment of the present disclosure, in the semiconductor device, resistance values of a power supply line and a ground line can be reduced. Further, according to an embodiment of the present disclosure, in the semiconductor device, efficiency of heat dissipation of a power supply line and a ground line can be increased.

The present disclosure may include, for example, following configurations.

### Appendix 1

A semiconductor device including:
a substrate having a first main surface and a second main surface;
a plurality of elements formed on the first main surface of the substrate or above the first main surface;
at least one first power supply line electrically connected to at least one of the plurality of elements, disposed in a first layer provided above the first main surface of the substrate, and having an upper surface, a first side surface continuously formed from the upper surface, and a second side surface that is opposite to the first side surface and continuously formed from the upper surface; and
at least one second power supply line disposed in the first layer and a second layer above the first layer and disposed from the second layer to the first layer to cover the upper surface, the first side surface, and the second side surface in a part of the at least one first power supply line.

### Appendix 2

The semiconductor device described in appendix 1, further including
at least two signal lines electrically connected to at least one of the plurality of elements and disposed in at least the first layer.

### Appendix 3

The semiconductor device described in appendix 2, wherein
the at least two signal lines are disposed from the second layer to the first layer.

### Appendix 4

The semiconductor device described in appendix 2 or 3, further including:
a first dielectric film disposed between the at least two signal lines in the first layer and having a first dielectric constant, and
a second dielectric film disposed between the at least one first power supply line and the at least one second power supply line in the first layer and having a second dielectric constant higher than the first dielectric constant.

### Appendix 5

The semiconductor device described in any one of appendixes 2 to 4, wherein,
in the first layer, a distance between the at least two signal lines is greater than a distance between the at least one first power supply line and the at least one second power supply line.

### Appendix 6

The semiconductor device described in any one of appendixes 2 to 4, wherein,
in the first layer, each of the at least two signal lines includes a wiring portion and a plug portion,
in the first layer, the at least one first power supply line includes a wiring portion and a plug portion, and
a length of the plug portion of each of the at least two signal lines is greater than a length of the plug portion of the at least one first power supply line.

### Appendix 7

The semiconductor device described in any one of appendixes 1 to 6, wherein
the at least one first power supply line and the at least one second power supply line are disposed to intersect each other in a plan view of the first main surface.

### Appendix 8

The semiconductor device described in any one of appendixes 2 to 7, wherein
a cross-sectional area of the at least one first power supply line is greater than a cross-sectional area of each of the at least two signal lines.

### Appendix 9

The semiconductor device described in any one of appendixes 1 to 8, wherein
the second power supply line is a ground line.

### Appendix 10

A semiconductor device including:
a substrate having a first main surface and a second main surface;
a plurality of elements formed on the first main surface of the substrate or above the first main surface;
at least one first power supply line electrically connected to at least one of the plurality of elements, disposed in a first layer provided below the second main surface of the substrate, and having a lower surface, a first side surface continuously formed from the lower surface, and a second side surface that is opposite to the first side surface and continuously formed from the lower surface; and
at least one second power supply line disposed in the first layer and a second layer below the first layer and disposed from the second layer to the first layer to cover the lower surface, the first side surface, and the second side surface in a part of the at least one first power supply line.

### Appendix 11

The semiconductor device described in appendix 10, further including
at least two signal lines electrically connected to at least one of the plurality of elements and disposed in a third layer that is provided above the first main surface.

### Appendix 12

The semiconductor device described in appendix 10 or 11, wherein
the second power supply line is a ground line.

### Appendix 13

A semiconductor device manufacturing method comprising:
providing a substrate having a first main surface and a second main surface;
forming a plurality of elements on the first main surface of the substrate or above the first main surface;
forming at least one first power supply line electrically connected to at least one of the plurality of elements, disposed in a first layer provided above the first main surface of the substrate, and having a lower surface, a first side surface continuously formed from the lower surface, and a second side surface that is opposite to the first side surface and continuously formed from the lower surface; and
forming at least one second power supply line disposed in a second layer above the first layer and disposed from the second layer to the first layer to cover the lower surface, the first side surface, and the second side surface in a part of the at least two power supply line.

In the above-described exemplary embodiments, a semiconductor device and a semiconductor device manufacturing method may be modified in various ways without departing from the scope and idea of the present disclosure. For example, some components in an embodiment may be added to another embodiment within the ordinary creative range of a person skilled in the art. Some components in an embodiment may be replaced with corresponding components in another embodiment.

### REFERENCE SIGNS LIST

10 . . . . . . substrate, 12 . . . . . . first main surface, 14 . . . . . . second main surface, 22 . . . . . . element, 24 . . . . . . dielectric film, 24, 26 . . . . . . plug, 32, 34, 42, 44, 52, 54, 62, 64, 72, 74, 82, 84 . . . . . . dielectric film, 46, 56 . . . . . . wire, 36, 46, 56, 66 . . . . . . wire, 36a, 46a, 56a, 66a, 76a, 78a, 86a, 86b . . . . . . wiring portion, 36b, 46b, 56b, 66b, 76b, 78b, 86c . . . . . . plug portion, 76 . . . . . . power supply line, 76a . . . . . . wiring portion, 76b . . . . . . plug portion, 78 . . . . . . signal line, 86 . . . . . . ground line, 88 . . . . . . signal line, 100 . . . . . . semiconductor device

1. A semiconductor device including:
a substrate having a first main surface and a second main surface;
a plurality of elements formed on the first main surface of the substrate or above the first main surface;
at least one first power supply line electrically connected to at least one of the plurality of elements, disposed in a first layer provided above the first main surface of the substrate, and having an upper surface, a first side surface continuously formed from the upper surface, and a second side surface that is opposite to the first side surface and continuously formed from the upper surface; and
at least one second power supply line disposed in the first layer and a second layer above the first layer and disposed from the second layer to the first layer to cover the upper surface, the first side surface, and the second side surface in a part of the at least one first power supply line.

2. The semiconductor device according to claim 1, further comprising:
at least two signal lines electrically connected to at least one of the plurality of elements and disposed in at least the first layer.

3. The semiconductor device according to claim 2, wherein
the at least two signal lines are disposed from the second layer to the first layer.

4. The semiconductor device according to claim 2, further comprising:
a first dielectric film disposed between the at least two signal lines in the first layer and having a first dielectric constant; and
a second dielectric film disposed between the at least one first power supply line and the at least one second power supply line in the first layer and having a second dielectric constant higher than the first dielectric constant.

5. The semiconductor device according to claim 2, wherein,
in the first layer, a distance between the at least two signal lines is greater than a distance between the at least one first power supply line and the at least one second power supply line.

6. The semiconductor device according to claim 2, wherein,
in the first layer, each of the at least two signal lines includes a wiring portion and a plug portion,
in the first layer, the at least one first power supply line includes a wiring portion and a plug portion, and
a length of the plug portion of each of the at least two signal lines is greater than a length of the plug portion of the at least one first power supply line.

7. The semiconductor device according to claim 1, wherein
the at least one first power supply line and the at least one second power supply line are disposed to intersect each other in a plan view of the first main surface.

8. The semiconductor device according to claim 2, wherein
a cross-sectional area of the at least one first power supply line is greater than a cross-sectional area of each of the at least two signal lines.

9. The semiconductor device according to claim 1, wherein
the second power supply line is a ground line.

10. A semiconductor device including:
a substrate having a first main surface and a second main surface;
a plurality of elements formed on the first main surface of the substrate or above the first main surface;
at least one first power supply line electrically connected to at least one of the plurality of elements, disposed in a first layer provided below the second main surface of the substrate, and having a lower surface, a first side surface continuously formed from the lower surface, and a second side surface that is opposite to the first side surface and continuously formed from the lower surface; and
at least one second power supply line disposed in the first layer and a second layer below the first layer and disposed from the second layer to the first layer to cover the lower surface, the first side surface, and the second side surface in a part of the at least one first power supply line.

11. The semiconductor device according to claim 10, further comprising:
at least two signal lines electrically connected to at least one of the plurality of elements and disposed in a third layer that is provided above the first main surface.

12. The semiconductor device according to claim 10, wherein
the second power supply line is a ground line.

13. A semiconductor device manufacturing method comprising:
providing a substrate having a first main surface and a second main surface;
forming a plurality of elements on the first main surface of the substrate or above the first main surface;
forming at least one first power supply line electrically connected to at least one of the plurality of elements, disposed in a first layer provided above the first main surface of the substrate, and having a lower surface, a first side surface continuously formed from the lower surface, and a second side surface that is opposite to the first side surface and continuously formed from the lower surface; and
forming at least one second power supply line disposed in a second layer above the first layer and disposed from the second layer to the first layer to cover the lower surface, the first side surface, and the second side surface in a part of the at least two power supply line.
